(19) United States
(12) Patent Application Publication
(10) Pub. No.: US 2010/0258784 A1
(43) Pub. Date: Oct. 14, 2010

(54) Method Of Efficient Coupling Of Light From Single-Photon Emitter To Guided Radiation Localized To Sub-Wavelength Dimensions On Conducting Nanowires

(76) Inventors: Mikhail D. Lukin, Cambridge, MA (US); Alexander S. Zibrov, Cambridge, MA (US); Alexey V. Akimov, Cambridge, MA (US); Philip R. Hemmer, College Station, TX (US); Hongkun Park, Lexington, MA (US); Aryesh Mukherjee, West Bengal (IN); Darrick E. Chang, Pasadena, CA (US); Chun Liang Yu, Cambridge, MA (US)

Correspondence Address: 24IP LAW GROUP USA, PLLC, 12 E. LAKE DRIVE, ANNAPOLIS, MD, 21403, US

(21) Appl. No.: 12/678,907

(22) PCT Filed: Sep. 18, 2008
(86) PCT No.: PCT/US08/76906

§ 371 Date: Mar. 18, 2010

Related U.S. Application Data
(60) Provisional application No. 60/973,288, filed on Sep. 18, 2007.

(51) Int. Cl. H01L 29/66; G02B 6/00; H01L 31/0232; F21V 8/00; G02B 6/26

(52) U.S. Cl. 257/10; 250/459.1; 250/227.24; 385/15; 977/762; 977/774; 977/933; 977/936; 977/957; 977/954; 977/950; 257/E29.168

(57) ABSTRACT

A cavity free, broadband approach for engineering photon emitter interactions via sub-wavelength confinement of optical fields near metallic nanostructures. When a single CdSe quantum dot (QD) is optically excited in close proximity to a silver nanowire (NW), emission from the QD couples directly to guided surface plasmons in the NW, causing the wire's ends to light up. Nonclassical photon correlations between the emission from the QD and the ends of the NW demonstrate that the latter stems from the generation of single, quantized plasmons. Results from a large number of devices show that the efficient coupling is accompanied by more than 2.5-fold enhancement of the QD spontaneous emission, in a good agreement with theoretical predictions.

### CROSS-REFERENCE TO RELATED APPLICATIONS

The present application claims the benefit of the filing date of U.S. Provisional Patent Application Ser. No. 60/973,288 filed on Sep. 18, 2007 and entitled “Method Of Efficient Coupling Of Light From Single-Photon Emitter To Guided Radiation Localized To Sub-Wavelength Dimensions On Conducting Nanowires.”

The above-referenced provisional patent application is hereby incorporated by reference herein in its entirety.

### STATEMENT REGARDING FEDERALLY SPONSORED RESEARCH OR DEVELOPMENT

The present invention may have been developed with funding from one or more of the following government contracts: DARPA FA9550-04-1-0455, NSF (Career) PHY 0134776, NSF (NIRT) ECCS-0708905, NSF (CUA) PHY 0551153, DTO ARO STIC W911NF-05-1-0476, and NSF (NIRT) ECS-0210426.

### BACKGROUND OF THE INVENTION

1. Field of the Invention

The present invention relates to a broadband approach for engineering photon-emitter interactions via sub-wavelength confinement of optical fields near metallic nanostructures.

2. Brief Description of the Related Art

Control over the interaction between single photons and individual optical emitters is an outstanding problem in quantum science and engineering. It is of interest for the ultimate control over light quanta, as well as for potential applications such as efficient photon collection, single photon switching and long range optical coupling of quantum bits. See, Yamamoto, Y., Imamoglu, A., “Mesoscopic Quantum Optics,” John Wiley & Sons, Inc. (New York), (1999); McKeever, J., Boca, A., Boozer, A. D., Miller, R., Buck, J. R., Kuzmich, A., Kimble, H. J., “Deterministic Generation of Single Photons from One Atom Trapped in a Cavity,” Science 303, 1992 (2004); Birnbaum, K. M., Boca, A., Miller, R., Boozer, A. D., Northup, T. E., Kimble, H. J., “Photon blockade in an optical cavity with one trapped atom,” Nature 436, 87 (2005); Cirac, J. I., Zoller, P., Kimble, H. J., Mabuchi, H., “Quantum State Transfer and Entanglement Distribution among Distant Nodes in a Quantum Network,” Phys. Rev. Lett. 78(16), 3221 (1997); Imamo\check{g}lu, A., Awschalom, D. D., Burkard, G., DiVincenzo, D. P., Loss, D., Sherwin, M., Small, A., “Quantum Information Processing Using Quantum Dot Spins and Cavity QED,” Phys. Rev. Lett. 83(20), 4204 (1999). Recently, remarkable advances have been made towards these goals, based on modifying photon fields around an emitter using high finesse optical cavities. See, Englund, D., Fattal, D., Waks, E., Solomon, G., Zhang, B., Nakaoka, T., Arakawa, Y., Yamamoto, Y., Vuckovic, J., “Controlling the Spontaneous Emission Rate of Single Quantum in a Two-Dimensional Photonic Crystal,” Phys. Rev. Lett. 95, 013904 (2005); Hennessy, K., Badolato, A., Winger, M., Gerace, D., Atatüre, S., Hu, E. L., Imamo\check{g}lu, A., “Quantum nature of a strongly coupled single quantum dot cavity system,” Nature 445, 896, (2007); Pinkse, P. W. H., Fischer, T., Maunz, P., Rempe, G., “Trapping an atom with single photons,” Nature 404, 365 (2000).

Surface plasmons, or surface plasmon polaritons (SPs), are propagating excitations of charge-density waves and their associated electromagnetic fields on the surface of a conductor. Much like the optical modes of a conventional dielectric fiber, a broad continuum of SP modes can be confined on a cylindrical metallic wire and guided along the wire axis (FIG. 1A). However, compared to dielectric waveguides, the thin wires can maintain propagation of SP modes localized transversely to dimensions comparable to the wire diameter d, even when it is much smaller than the optical wavelength λ. This sub-wavelength localization is accompanied by a dramatic concentration of optical fields. In addition, the SP modes propagate with greatly reduced velocities because they involve the motion of charge-density waves. See, Takahara, J., Yamagishi, S., Taki, H., Morimoto, A., Kobayashi, T., “Guiding of a one-dimensional optical beam with nanometer diameter,” Opt. Lett. 22(7), 475 (1997); Chang, D. E., Sorensen, A. S., Hemmer, P. R., Lukin, M. D., “Strong coupling of single emitters to surface plasmons,” quant-ph, 0603221 (2006).

The unique properties of nanoscale SPs have recently been explored in a variety of fascinating systems, ranging from transmission and waveguiding through sub-wavelength structures to biomedical devices and proposals for realizing “perfect” lenses and invisibility cloaks. Enhancement of fluorescence, polarization-dependent coupling and normal mode splitting near the sub-wavelength structures have also recently been observed. See, Hochberg, M., Baehr-Jones, T., Walker, C., Scherer, A., “Integrated plasmon and dielectric waveguides,” Optics Express 12(22), 54811 (2004); Biteen, J. S., Lewis N. S., Atwater H. A., “Spectral tuning of plasmon-enhanced silicon quantum dot luminescence,” Appl. Phys. Lett. 88, 131109 (2006); Zhang, J., Ye, Y. H., Wang, X., Rochon, P., Xiao, M., “Coupling between semiconductor quantum dots and two-dimensional surface plasmons,” Phys. Rev. B 72, 201306(R) (2005); Mertens, H., Biteen, J. S., Atwater, H. A., Polman, A., “Polarization-Selective Plasmon Enhanced Silicon Quantum-Dot Luminescence,” Nano. Lett. 6, 2622 (2006); Dintinger J., Klein, S., Bustos, F., Barnes, W. L., Ebbesen, T. W., “Strong coupling between surface plasmon-polaritons and organic molecules in sub-wavelength hole arrays,” Phys. Rev. B 71, 035424 (2005).

### SUMMARY OF THE INVENTION

The present invention extends these developments in two principal directions. First, the present invention results simultaneously in significant enhancement of SP emission and efficient collection into guided modes propagating along a well-defined direction. Second, it establishes direct coupling between individual emitters and individual, quantized SPs. It thus bridges the fields of nanoscale plasmonics and quantum optics, and opens up the possibility of using quantum optical techniques to achieve new levels of control over the interaction of single SPs and to realize novel quantum plasmonic devices. In conventional setups, the benefits of using smaller wires must be balanced against poor out-coupling to free-space modes. However, this tradeoff can be circumvented by the present invention by using optimized geometries (e.g., SPs on conducting nanotips) and evanescent out-coupling to mode-matched optical fibers. The excellent coupling expected from these integrated systems can be uniquely used, e.g., for efficient single-photon sources, high resolution microscopy and sensing, or long-range quantum bit coupling. See, Klimov, V. V., Ducloy, M., Letokhov, V. S., “A model of an apertureless scanning microscope with a prolate nanospheroid as a tip and an excited molecule as an object,” Chem. Phys. Lett. 358,192 (2002). Furthermore, in such systems an individual emitter can be made optically opaque to incident, localized single SPs, which can be used to produce large optical nonlinearities for realization of single photon switches and photonic transistors. See, Chang, D. E., Sørensen, A. S., Demler, E. A., Lukin, M. D. “A single-photon transistor using nano-scale surface plasmons”, quant-ph/0706.4335. Beyond these specific applications, the ability to create and control individual quanta of radiation with sub-wavelength localization may open up intriguing possibilities on the interface of several areas of optics and electronics.

In a preferred embodiment, the present invention is a method for manipulating optical radiation of a single emitter. The method comprises the steps of providing a photon source, providing a nanoscale optical emitter, providing a conducting nanowire of sub-wavelength dimension in close proximity to said nanoscale optical emitter to capture a majority of spontaneous radiation from the emitter into guided modes, and controlling and guiding optical plasmons in a specific direction using said conducting nanowire. The conducting nanowire preferably has a diameter of less than about 200 nm. In one embodiment, the nanowire has a diameter of approximately 100 nm.

In another embodiment, the present invention is a single photon transistor. The transistor comprises an optical emitter, a photon source, a photon detector, and plasmonic nanowires for connecting said optical source to said detector. Communication between said photon source and said detector is turned on and off by the presence of optical excitation within said optical emitter. The photon source may be, for example, a laser or an electrically driven diode. The detector may be, for example, an electrical detector or an optical detector.

In another preferred embodiment, the present invention is a method for manipulating optical radiation of a single emitter. The method comprises the step of controlling and guiding optical plasmons in a specific direction using conducting nanowires with sub-wavelength dimensions.

In another preferred embodiment, the present invention is a method for forming an efficient quantum interface between photonic and matter quantum bits. The method comprises the step of creating strong coupling between single optical plasmons guided on nanowires and single emitters.

In another preferred embodiment, the present invention is a method for efficient creation of single photons for quantum cryptography. The method comprises the step of creating strong coupling between single optical plasmons guided on nanowires and single emitters to form an efficient quantum interface between photonic and matter quantum bits.

In another preferred embodiment, the present invention is a method for connecting quantum bits for quantum computation. The method comprises the step of creating strong coupling between single optical plasmons guided on nanowires and single emitters to form an efficient quantum interface between photonic matter and bits.

In another preferred embodiment, the present invention is a method for performing nano-scale efficient optical sensing. The method comprises the step of creating strong coupling between single optical plasmons guided on nanowires and single emitters to form an efficient quantum interface between photonic matter and bits.

In another preferred embodiment, the present invention is a system for realization of photon transistor. The system comprises a strong coupling between single optical plasmons guided on nanowires and single emitters.

In another preferred embodiment, the present invention is a system for realization of efficient nonlinear optical devices. The system comprises strong coupling between single optical plasmons guided on nanowires and single emitters.

Still other aspects, features, and advantages of the present invention are readily apparent from the following detailed description, simply by illustrating a preferable embodiments and implementations. The present invention is also capable of other and different embodiments and its several details can be modified in various obvious respects, all without departing from the spirit and scope of the present invention. Accordingly, the drawings and descriptions are to be regarded as illustrative in nature, and not as restrictive. Additional objects and advantages of the invention will be set forth in part in the description which follows and in part will be obvious from the description, or may be learned by practice of the invention.

### BRIEF DESCRIPTION OF THE DRAWINGS

For a more complete understanding of the present invention and the advantages thereof, reference is now made to the following description and the accompanying drawings, in which:

FIG. 1(a) illustrates a coupling between a QD and conducting NW. The QD can either spontaneously emit into free space or into the SPs.

FIG. 1(b) illustrates theoretical dependence of the total spontaneous emission rate (solid lines 110, 120, normalized by the uncoupled rate Γ₀) and efficiency of emission into SPs (dashed lines, 112, 122) on the distance of the emitter from the NW edge. The curves 110, 112 correspond to a wire with a 100 nm diameter while curves 120, 122 correspond to a wire with a 50 nm diameter.

FIG. 1(c) shows simulations of the electric field amplitude (arbitrary units) emitted by a dipole 130, positioned 25 nm from one end of a conducting NW 140. The wire is 3 μm in length and 50 nm in diameter. The field profile indicates strong emission into the guided SPs of the NW. Upon hitting the far end of the NW, some of the SP energy is clearly scattered into the far-field with some angular dependence 0, while the remaining is either lost to dissipation or to back-reflection. Note that the vertical scale is enlarged compared to the horizontal in order to clearly show the near field of the SPs. The interference of the back-reflected and forward propagating SPs is clearly visible as oscillations of the field along the NW.

FIG. 1(d) shows the amplitude of the Poynting vector of the light scattered from the far end of the NW, as a function of emission angle θ (see FIG. 1C), for wires of diameter 100 nm (150), 50 nm (160), 25 nm (170).

FIG. 2(a) is a diagram of a three-channel confocal microscope and a layout of sample containing QDs and NWs. A 532 nm laser serves as the excitation source, and collection is through a high numerical aperture objective lens (NA 1.3).

FIG. 2(b) is a collection of images taken with channels I, II, III, showing coupling of QD radiation to SPs. The first image is of a NW taken with Ch I. The second is an image of QDs taken with Ch II. The circle 230 in the second figure corresponds to the position of the coupled QD, and the same point is also denoted in the first image as circle 220. The third image was taken with Ch III. The excitation laser was focused on the QD 240. The largest bright spot corresponds to the QD fluorescence, while two smaller spots correspond to SPs scattered from the NW ends. The circle 250 indicates the furthest end of the NW, used for photon cross correlation measurements (see FIG. 3).

FIG. 3(a) is time trace of fluorescence counts (310) from a coupled QD and scattered light (320) from the end of the NW to which it is coupled. Fluctuations are due to QD blinking.

FIG. 3(b) illustrates is a second-order correlation function G⁽²⁾(τ) (corresponding to the number of coincidences between the two channels) of QD fluorescence. The number of coincidences at τ=0 goes almost to zero, confirming that the QD is a single-photon source. The width of the dip depends on the total decay rate Γₜₒₜₐₗ and the pumping rate R.

FIG. 3(c) illustrates a second-order cross-correlation function between fluorescence of the QD and scattering from the NW end. This data was taken by detecting coincidences between Ch II (QD) and Ch III (wire end) in the experimental setup.

FIG. 4(a) illustrates the linear dependence of the width of the G⁽²⁾ dip on laser excitation power can be extrapolated to zero power, yielding the total spontaneous emission rate of a QD.

FIG. 4(b) illustrates normalized histograms of QD lifetimes. The black curve corresponds to the distribution of uncoupled QDs (100 data points) and grey to coupled QDs (30 points). The mean lifetimes for uncoupled and coupled dots are 22 ns±5 ns and 13 ns±4 ns respectively.

FIG. 4(c) illustrates average enhancement of coupled systems as a function of PMMA thickness. The gray columns indicate the standard deviations of the obtained distributions. The rectangle 410, 420, 430 indicates the average values observed.

FIG. 4(d) illustrates a measured maximum and average efficiencies of emission into the SPs as a function of PMMA thickness, as determined from count rates obtained from the QD and wire ends. The triangles indicate average (maximum) apparent efficiencies ηₘ of the coupled systems, without compensating for SP losses. The diamonds indicate the maximum actual efficiency η, after compensating for the dissipation losses of the NWs.

### DETAILED DESCRIPTION OF THE PREFERRED EMBODIMENTS

The present disclosure demonstrates a cavity free, broadband approach for engineering photon emitter interactions via sub-wavelength confinement of optical fields near metallic nanostructures. For background, see Chang, D. E., Sørensen, A. S., Hemmer, P. R., Lukin, M. D., “Quantum Optics with Surface Plasmons,” Phys. Rev. Lett. 97, 053002 (2006); Atwater, H. A., “The promise of plasmonics,” Scientific American 296(4), 56 (2007); Genet, C., Ebbesen, T. W., “Light in tiny holes,” Nature 445, 39 (2007). When a single CdSe quantum dot (QD) is optically excited in close proximity to a silver nanowire (NW), emission from the QD couples directly to guided surface plasmons in the NW, causing the wire's ends to light up. Sanders, A. W., Routenberg, D. A., Wiley, B. J., Xia, Y., Dufresne, E. R., Reed, M. A., “Observation of Plasmon Propagation, Redirection, and FanOut in Silver Nanowires,” Nano Lett. 6(8), 1822 (2006); Ditlbacher, H., Hohenau, A., Wagner, D., Kreibig, U., Rogers, M., Hofer F., Aussenegg F. R., Krenn, J. R., “Silver Nanowires as Surface Plasmon Resonators,” Phys. Rev. Lett. 95, 257403 (2005). Nonclassical photon correlations between the emission from the QD and the ends of the NW demonstrate that the latter stems from the generation of single, quantized plasmons. Results from a large number of devices show that the efficient coupling is accompanied by more than 2.5-fold enhancement of the QD spontaneous emission, in a good agreement with theoretical predictions.

The emission properties of a nanoscale optical emitter can be significantly modified by the proximity of a NW that supports SPs. In principle, three distinct decay channels exist. First, direct optical emission into free-space modes is possible, with a rate modified from its free-space value due to the proximity of the metallic surface. See, Chance, R. R., Prock, A., Silbey, R., “Molecular fluorescence and energy transfer near interfaces,” Adv. Chem. Phys. 37, 1 (1978). Second, the optical emitter can be damped non-radiatively due to the Ohmic losses in the conductor. Most importantly, the tight field confinement and reduced velocity of SPs can cause the NW to capture a majority of spontaneous radiation into the guided SP modes, much like a lens with extraordinarily high numerical aperture. For an optical emitter placed within the evanescent SP mode tail, the spontaneous emission rate into the guided SP modes is proportional to (λ/d). In contrast, the free-space emission rate can be enhanced by at most a factor of four, whereas non-radiative damping becomes significant only for very small wire-emitter separation. Thus, for an optimally placed emitter the spontaneous emission rate Γₚₗ into SPs can far exceed the radiative and non-radiative rates (Γ_{rad} and Γ_{nrd}, respectively), which results in highly efficient generation of guided SPs and the resultant enhancement of the total decay rate (Γₜₒₜₐₗ) compared to that of an uncoupled emitter (Γ₀). This enhancement can be characterized by a Purcell factor P=Γₜₒₜₐₗ/Γ₀, which for thin wires is predicted to be large. The resulting strong coupling is caused by the geometrical effect of tight transverse confinement of the SPs and occurs far away from the plasmon resonance frequency of NWs. See, Sun, Y., Gates, B., Mayers, B., Xia, Y., “Crystalline Silver Nanowires by Soft Solution Processing,” Nano. Lett. 2, 165 (2002). It does not involve an optical cavity, and can be achieved simultaneously over a broad continuum of optical frequencies.

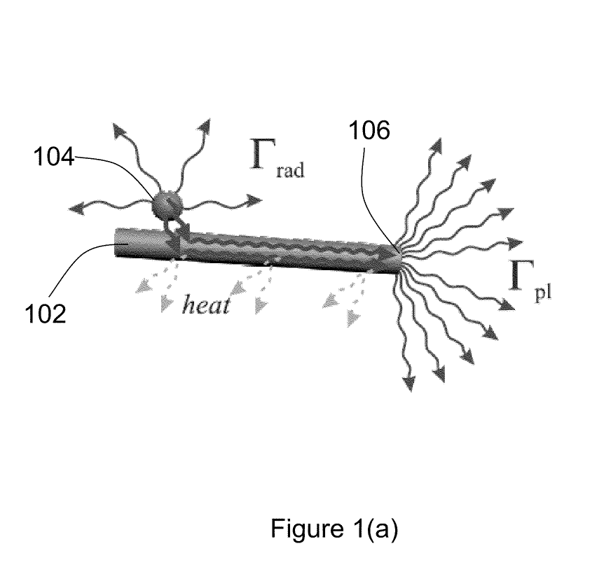

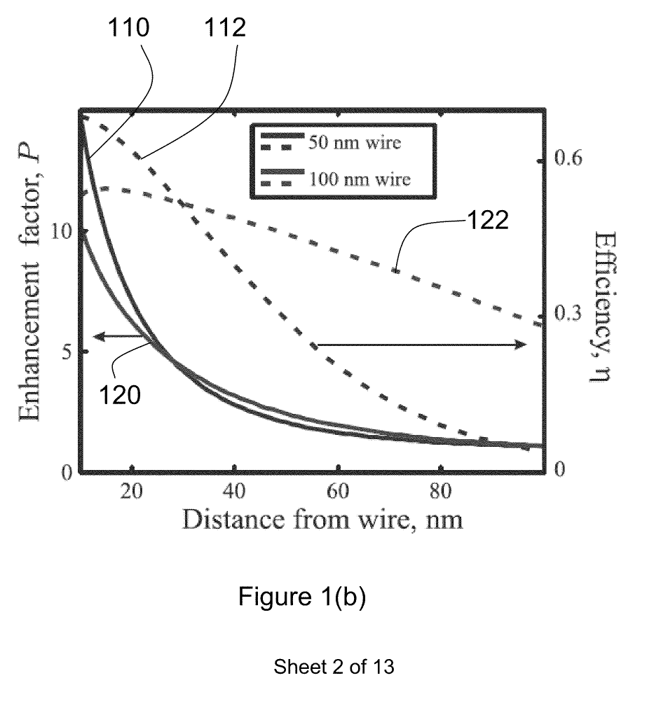

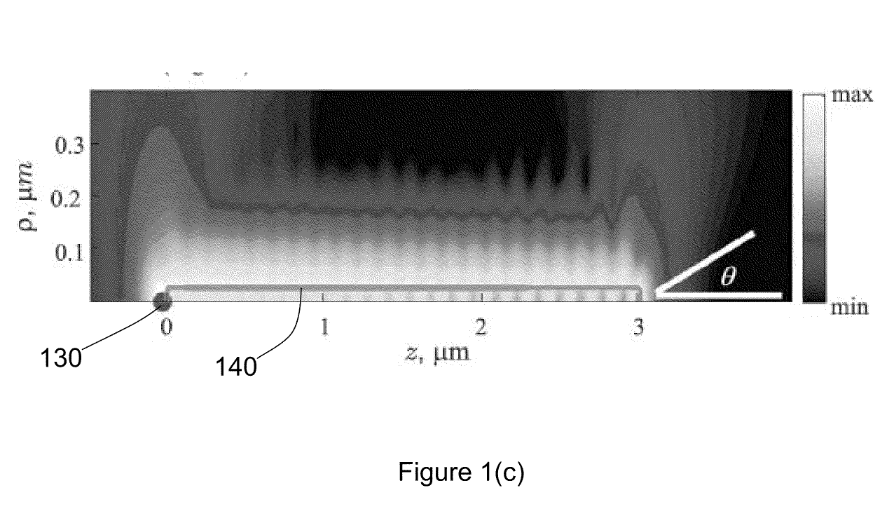

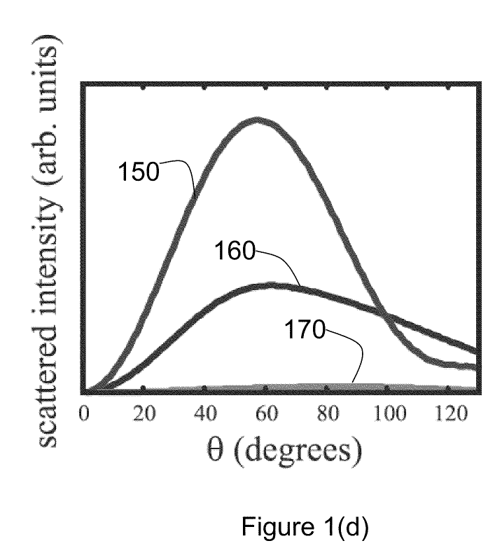

Chemically synthesized CdSe quantum dots (QDs) placed proximally to silver NWs comprise a simple experimental system to investigate the emitter-SP coupling. See, Chung, I., Witkoskie, J. B., Cao, J., Bawendi, M. G., “Description of the fluorescence intensity time trace of collections of CdSe nanocrystal quantum dots based on single quantum dot fluorescence blinking statistics,” Phys. Rev. E 73, 011106 (2006). As illustrated in FIG. 1(a), the spontaneous emission of a QD is split between photon emission into free space, which can be detected by an optical microscope, and the excitation of SPs (Γ_{nrd} is negligible for the chosen parameters, as described below). During propagation along the smooth NW 102, SPs 104 do not couple to the observable far-field modes of the surrounding dielectric. However, much like a conventional antenna, an abrupt end 106 of the wire 102 can scatter SPs radiatively into far-field modes, thus facilitating their detection using an optical microscope. A simulation of this effect is shown in FIG. 1(c), where a QD is placed 25 nm away from one wire end: whereas the SPs decay evanescently away from the NW edge, substantial emission into free space results from SP scattering at the far end of the wire.

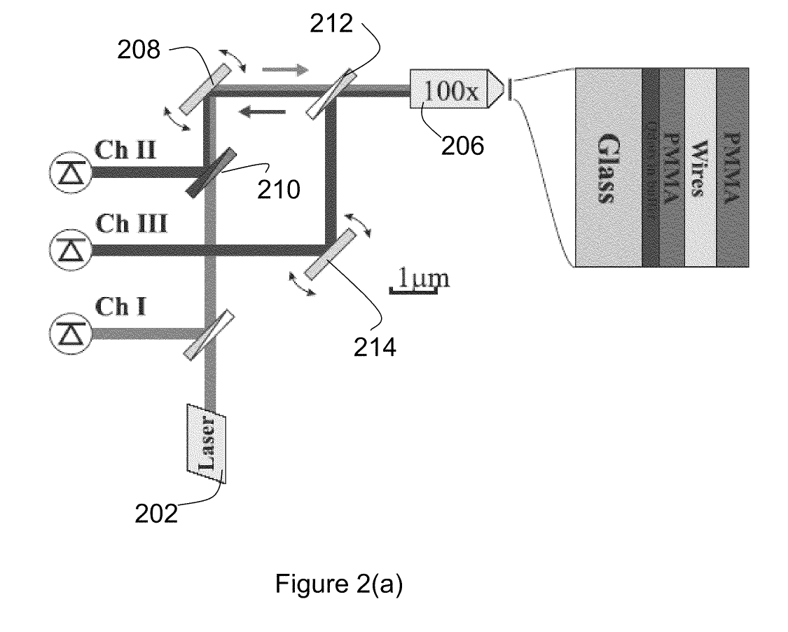

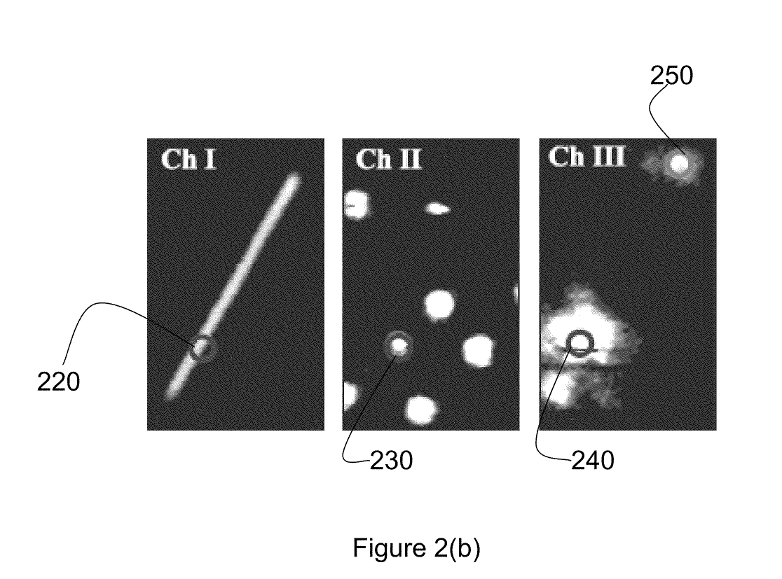

Silver NWs were prepared using a solution-phase polyol method with modifications for surface passivation. Tao, A., Kim, F., Hess, C., Goldberger, J., He, R., Sun, Y., Xia, Y., Yang, P. Langmuir-Blodgett, “Silver Nanowire Monolayers for Molecular Sensing Using Surface Enhanced Raman Spectroscopy,” Nano Lett. 3, 1229 (2003). More specifically, samples were prepared by spin-coating a solution of chemically synthesized CdSe QDs (mixed with Na₂B₄O₇ and cysteine) onto a plasma-cleaned glass slide at 3000 rpm for 60 sec under nitrogen atmosphere. Three minutes later, PMMA (1,2,3 wt % in toluene for 30, 60 and 90 nm films) was spun on top at 6000 rpm for 60 sec. A stamp with the modified silver NWs was placed on top of the slide and pressed for a few seconds. The stamp was left there for 20 min and then gently peeled off, leaving NWs on the PMMA. Finally, PMMA (2.2 wt %) was spun on the top at 1000 rpm for 60 sec (see FIG. 2(b)).

Scanning electron microscopy images revealed that the diameters of silver NWs were 102±24 nm. The closest allowed distance between the QDs and NWs is determined by the thickness of the PMMA layer and the QD shell radius (˜5 nm) and is ˜35 nm. The experimental setup for studying the QDNW system (FIG. 2(a)) is based on a modified confocal microscope with three scanning channels. One channel (Ch I) was used for imaging NWs, and the second channel (Ch II) was used for imaging QDs. The third channel (Ch III), which can independently image any diffraction-limited spot within the field of view of the objective lens, was used to detect the scattered SPs from the NW ends.

In general, the coupling between an optical emitter and single SPs should be stronger for thinner wires (see FIG. 1(b)). However, for thinner wires, the outcoupling efficiency of SPs to far-field optical modes at the wire end decreases due to a large wavevector mismatch. In this case, significant SP reflection at the NW ends causes standing SP wave formation within the NW (FIG. 1(c)) and eventual energy loss due to heating (Ohmic losses). The effect of NW diameter on out-coupling efficiency is illustrated in FIG. 1(d), where the intensity of the scattered radiation from the wire end is plotted for different wire diameters. For a thin, 25 nm NW hardly any scattering is seen from the end despite the stronger coupling between the emitter and SPs, but the scattering is significant for a 100 nm wire (this was verified experimentally by exciting SPs directly with a laser focused at one wire end). Nanowires with d˜100 nm exhibit both reasonable emitter-SP couplings and SP to far-field scattering, and thus were chosen for the experiments. The large bandwidth of the SP-emitter coupling enables us to perform the experiments at room temperature, where a single QD spectral width exceeds 15 nm.

As shown in FIG. 2(a), the confocal microscope in the experimental setup used a cw 532 nm laser 202 as the excitation source. It is focused onto the sample using a Nikon CFI Plan Fluor 100× oil immersion objective NA 1.3 206, while a mirror 208 mounted on a galvanometer is used to scan the incoming beam. Ch II acts as a confocal microscope and is used to image single QDs, via fluorescence at 655 nm. Ch I is combined with Ch II using a 90:10 beam splitter 210 that directs part of the reflected laser light towards a detector and can be used to image the silver NWs. Ch III is combined with the main setup using a 50:50 beam splitter 212 and is an independent imaging system. It also includes a galvanometer 214 which allows us to image any diffraction limited spot within the field of view to detect fluorescence at 655 nm.

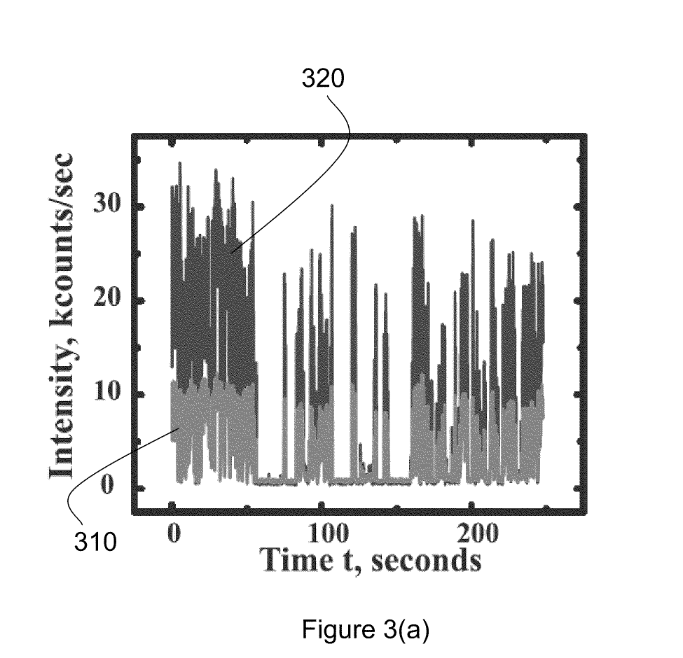

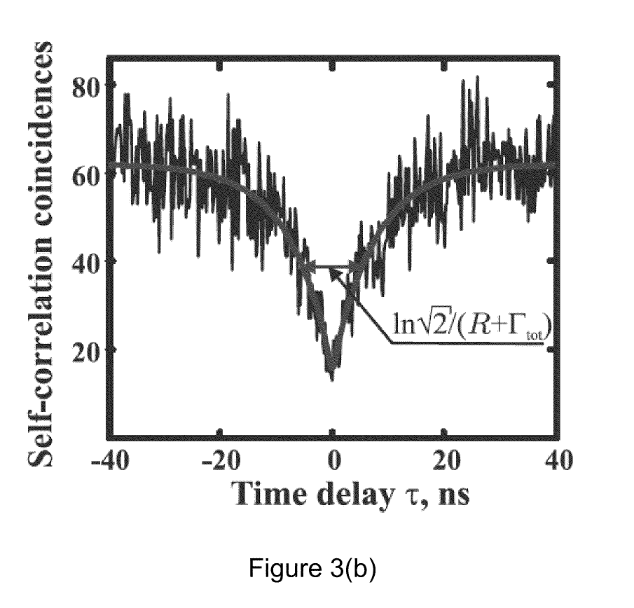

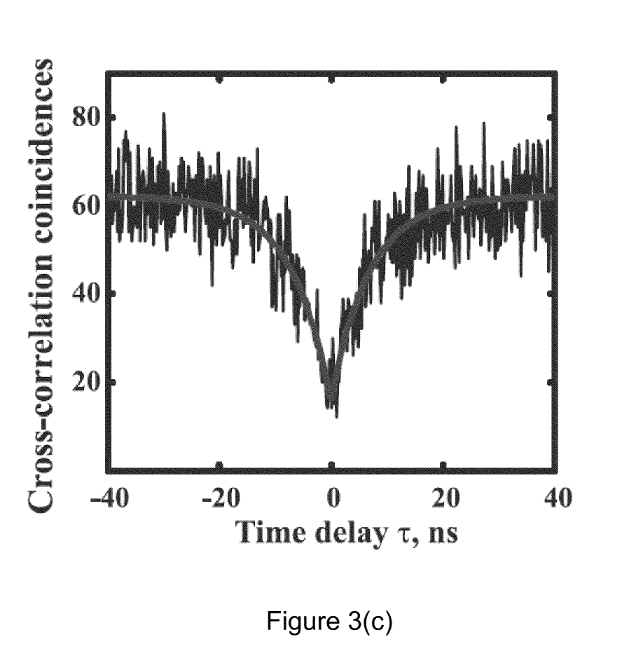

FIG. 2(b) presents an experimental demonstration of directed emission of a QD into SPs. The first figure in the series shows a confocal reflection image of a silver NW recorded with Ch I. The second corresponds to a fluorescence image of QDs detected at 655 nm with Ch II. These two images were used to determine the positions of the NW and QD relative to each other. Due to the resolution limit of the optical system, the actual distance between a QD and the NW could not be determined, and only QDs that appear directly on the top of a NW were chosen for experiment. The third figure shows a coupled wire-dot system imaged with Ch III. When the proximal QD was excited by the laser, the NW ends literally light up. The large spot in the center of the figure corresponds to emission from the QD itself, whereas the two other points coincide with the ends of the wire. Significantly, a high degree of correlation was seen between the time traces of the fluorescence counts from the QD and from the end of the wire to which the QD was coupled, as shown in FIG. 3(a). These observations indicate that the source of the fluorescence from the end of the wire is the QD.

Photon coincidence measurements of the QDs, shown in FIG. 3(b), demonstrate that the QDs used in these experiments can only emit a single photon at a time. In these measurements, the free space fluorescence from the QD was equally split into two channels using a beam splitter and detected by avalanche photodiodes. The coincidences between two channels were recorded as a function of time delay. If the QD emits only one photon at a time it can only be recorded at one of the channels, and therefore zero coincidences are expected between two channels at zero time delay as seen in FIG. 3(b). The slight offset from zero can be attributed to stray light, dark counts of the detectors and the resolution limit of the electronics.

The light emission at the NW end is a result of single, quantized SPs scattering off the ends of the NW. This is demonstrated in FIG. 3(c) by the dip at τ=0 in the photon coincidence measurements between the free-space fluorescence of the QD and the emission from the wire end. This near-zero coincidence is a consequence of the fact that the single photon emitted from a QD can either radiate into free space or into the SP modes but never both simultaneously.

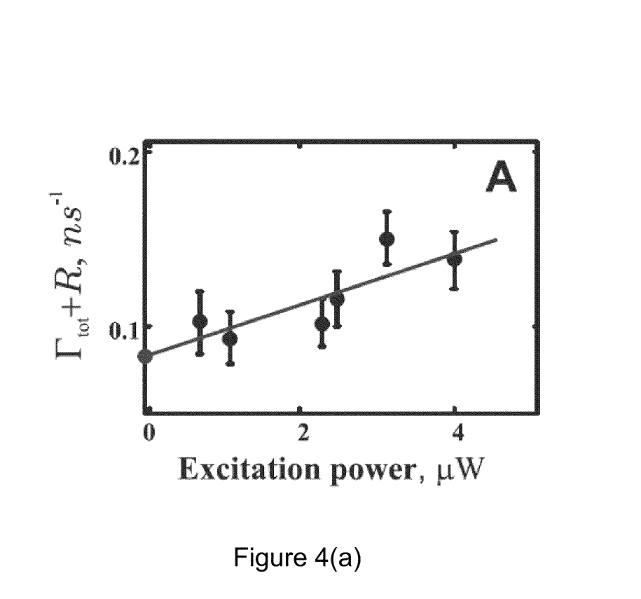

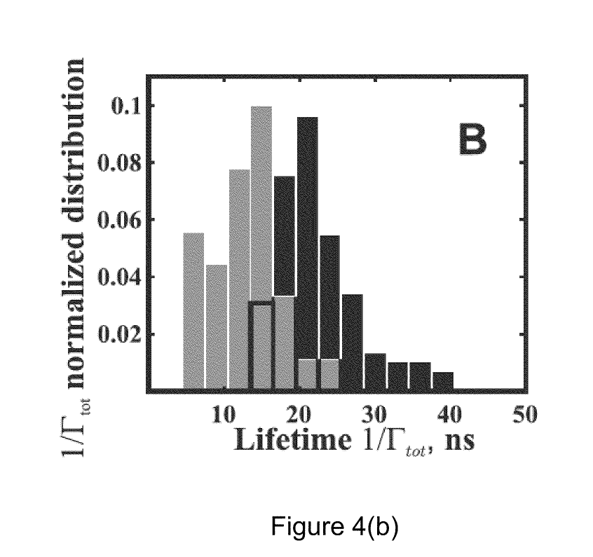

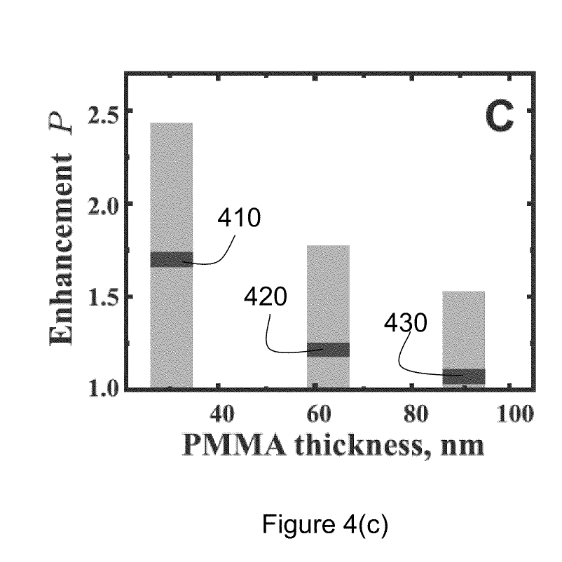

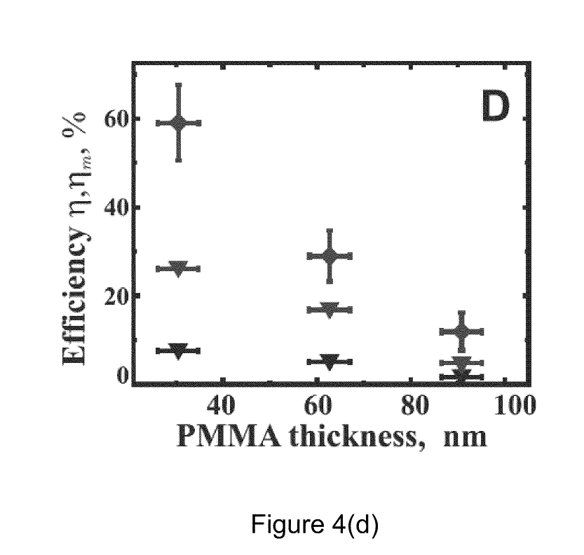

Data presented in FIGS. 3(a)-(c), along with measured count rates, can be used to quantify the coupling strength of the QD to the SP modes. Since the QD-SP coupling creates a new decay channel for the QD, its decay rate is expected to increase. To study this enhancement, observed coincidence data was fitted to a simple two-level model of QD emission, as shown in FIG. 3(b). See, Lounis, B., Bechtel, H. A., Gerion, D., Alivisatos, P., Moerner, W. E., “Photon antibunching in single CdSe/ZnS quantum dot fluorescence,” Chem. Phys. Lett 329, 399 (2000). The model incorporates an incoherent pumping rate R from the ground to excited state of a QD and a decay rate Γₜₒₜₐₗ back to the ground state. In this model, the temporal width of the anti-bunching dip is given by Δτ=ln \sqrt{2}/(R+Γₜₒₜₐₗ), where the excitation rate R is proportional to the incident power. Therefore, by extracting Δτ from coincidence measurements as a function of incident laser power and by extrapolating it to R=0, the total decay rate Γₜₒₜₐₗ can be obtained (FIG. 4(a)).

The natural lifetimes of individual dots (20-30 ns) vary from dot to dot due to the heterogeneity in their structures. However, the comparison of the lifetime distributions of 30 coupled and 100 uncoupled QDs shown in FIG. 4(b) clearly demonstrates that statistically the lifetime (decay rate) of the exciton in coupled QDs is shortened (enhanced). The average lifetime of the coupled (uncoupled) QDs was found to be 13 ns±4 ns (22 ns±5 ns). At the same time, the distribution for coupled QDs has a larger weight towards shorter lifetimes. It was found that certain coupled and uncoupled QDs exhibited lifetimes as short as 6 ns and 15 ns, respectively, indicating that P>2.5 is achieved for some coupled QD-NW systems. The apparent efficiency of emission into the SPs can be estimated by comparing the ratio of photon counts obtained directly from the dot and from the wire ends, ηₘ≈n_{ends}/(n_{dot}+n_{ends}), and is found to be ˜27% for the best coupled QD-NW system (see FIG. 4(c)). Note that this value does not account for the SPs that are dissipated before they reach the wire ends. Correcting for the measured average absorption lengths in the NWs allows us to deduce that the actual efficiency approaches η˜60±10%, directly demonstrating very efficient coupling to guided SPs.

The broadband nature of strong coupling is demonstrated by comparing the optical spectra associated with direct emission from the QD and from the wire end. For individual dots randomly drawn from an inhomogeneous ensemble with λ=655±15 nm, it was found that both the QD and wire-end emission exhibit identical ˜15 nm wide spectra. This is consistent with the ability of metallic wires to guide a broad range of optical frequencies and with theoretical predictions that strong coupling can be obtained for a broad continuum of frequencies away from the peak of the observed plasmon resonances. Dickson, R. M. and Lyon, L. A., “Unidirectional Plasmon Propagation in Metallic Nanowires,” J. Phys. Chem. B 104, 6095 (2000).

Further insight into the QD-SP coupling can be obtained by comparing these experimental observations with detailed electrodynamic calculations. The model of QD emission near a silver NW embedded in a dielectric medium includes losses as well as multiple SP modes. FIG. 1(b) shows the total spontaneous emission rates and the efficiency η=Γₚₗ/Γₜₒₜₐₗ for single SP generation as a function of QD distance from the wire (d=50 and 100 nm). Here the polarization of the QD transition was selected to be radially oriented, because this direction is expected to yield the dominant contribution to enhancement. For QDs positioned 35 nm from the wire and for a 100 nm wire, the calculation yields a Purcell factor P˜3.7. The lower enhancement observed experimentally can be attributed to the contributions from other polarization directions and the random positioning of the QDs away from the wire. For this distance of separation, the non-radiative decay rate (Γ_{non-rad}<0.05Γ₀) is predicted to be negligible. In addition to enhanced emission into guided SP modes, this theory also predicts a moderate increase in the radiative emission rate, a well-known phenomenon for dipoles oriented perpendicularly to a metallic surface. For the 100 nm wires and 35 nm NWQD distances, the plasmon generation efficiency η is theoretically estimated to be ˜50%, which is consistent with our observations as well.

Further comparison with theoretical predictions is obtained by repeating these observations with thicker PMMA layers (see FIGS. 4(c) and (d). These measurements demonstrate that both enhancement and estimated coupling efficiency rapidly decrease as the minimum QD-NW spacing increases, and become very small for PMMA thicknesses above 100 nm. These observations are also in good agreement with the above theoretical predictions.

When it comes to building practical quantum information systems, one would like to be able to combine the advantages of various different quantum bit systems. One example of such a hybrid approach involves a so-called quantum network, in which quantum states are stored and manipulated in matter qubits and, when desired, mapped into photons for long-distance transmission. The key challenge in making such a network is developing techniques for coherently transferring quantum states carried by photons into atoms and vice versa. The efficient coupling demonstrated with the present invention enables such an efficient light to matter quantum state transfer.

Such techniques for efficient optical sensing and manipulation at nanometer length scales have numerous applications in biological and medical imaging. In particular, the present invention allows for a unique combination of nanoscale resolution, high photon collection efficiency and ultra-high bandwidth. With this, many potential applications, e.g. in ultra-fast nonlinear optical nano-imaging, are possible.

In analogy with the electronic transistor, a photonic transistor is a device where a small optical gate field is used to control the propagation of another optical signal field via a nonlinear optical interaction. Its fundamental limit is the single-photon transistor, where the propagation of the signal field is controlled by the presence or absence of a single photon in the gate field. Nonlinear devices of this kind would have a number of interesting applications ranging from optical communication and computation to quantum information processing. However, their practical realization is challenging because the requisite single-photon nonlinearities are generally very weak. The method of the present invention achieves strong coupling between light and matter and makes use of the tight concentration of optical fields associated with guided surface plasmons (SPs) on conducting nanowires to achieve strong interaction with individual optical emitters. In essence, the tight localization of these fields causes the nanowire to act as a very efficient lens that directs the majority of the spontaneously emitted light into the SP modes, resulting in efficient generation of single plasmons (single photons). Such a system also allows for the realization of remarkable nonlinear optical phenomena, where individual photons strongly interact with each other. As an example, these nonlinear processes may be exploited to implement a single-photon transistor. While ideas for developing plasmonic analogues of electronic devices by combining SPs with electronics are already being explored, the method of the present invention opens up fundamentally new possibilities, in that it combines the ideas of plasmonics with the tools of quantum optics to achieve unprecedented control over the interactions of individual light quanta.

The foregoing description of the preferred embodiment of the invention has been presented for purposes of illustration and description. It is not intended to be exhaustive or to limit the invention to the precise form disclosed, and modifications and variations are possible in light of the above teachings or may be acquired from practice of the invention. The embodiment was chosen and described in order to explain the principles of the invention and its practical application to enable one skilled in the art to utilize the invention in various embodiments as are suited to the particular use contemplated. It is intended that the scope of the invention be defined by the claims appended hereto, and their equivalents. The entirety of each of the aforementioned documents is incorporated by reference herein.

1. A method for manipulating optical radiation of a single emitter, comprising:
providing a photon source;
providing a nanoscale optical emitter;
providing a conducting nanowire of sub-wavelength dimension in close proximity to said nanoscale optical emitter to capture a majority of spontaneous radiation from the emitter into guided modes; and
controlling and guiding optical plasmons in a specific direction using said conducting nanowire.

2. A method for manipulating radiation of a single emitter according to claim 1 wherein said conducting nanowire has a diameter of less than about 200 nm.

3. A method for manipulating radiation of a single emitter according to claim 1 wherein said conducting nanowire has a diameter of approximately 100 nm.

4. A single photon transistor comprising:
an optical emitter;
a photon source;
a photon detector; and
plasmonic nanowires for connecting said optical source to said detector;
wherein the communication between said photon source and said detector is turned on and off by the presence of optical excitation within said optical emitter.

5. A single photon transistor according to claim 4, wherein said photon source comprises a laser.

6. A single photon transistor according to claim 4, wherein said photon source comprises an electrically driven diode.

7. A single photon transistor according to claim 4, wherein said detector comprises an electrical detector.

8. A single photon source according to claim 4, wherein said detector comprises and optical detector.

9. (canceled)

10. (canceled)

11. A method for connecting quantum bits comprising the step of creating strong coupling between single or multiple optical plasmons guided on nanowires and single or multiple emitters to form an efficient quantum interface between photonic matter and bits.

12. A method for performing nano-scale efficient optical sensing comprising the step of creating strong coupling between single optical plasmons guided on nanowires and single or multiple optical emitters to achieve highly efficient collection of small signals from chemical and biological species.

13. An efficient nonlinear optical device comprising means for creating a strong coupling between single optical plasmons guided on nanowires and single emitters.

14. A method for connecting quantum bits according to claim 11, wherein said quantum bits are connected for quantum computation.

15. A method for connecting quantum bits according to claim 11, wherein said quantum bits are connected for quantum cryptography.
